(19) United States
(12) Patent Application Publication
(10) Pub. No.: US 2026/0344454 A1
(43) Pub. Date: Oct. 29, 2026

(54) PCB LABELING

(71) Applicant: CYBORD LTD., Tel Aviv (IL)

(72) Inventors: Eyal Isachar Weiss, Bnei Reem (IL); Zeev Efrat, Ramat Hasharon (IL); Asher Meir Cohen, Zichron Yaakov (IL)

(21) Appl. No.: 19/119,797

(22) PCT Filed: Oct. 17, 2023
(86) PCT No.: PCT/IL2023/051084

§ 371 Date: Apr. 10, 2025

Related U.S. Application Data
(60) Provisional application No. 63/417,063, filed on Oct. 18, 2022.

(51) Int. Cl. H10W 46/00

(52) U.S. Cl. CPC H10W 46/106; H10W 46/103; H10W 46/407; H10W 46/607

(57) ABSTRACT

A method of serializing printed circuit boards (PCBs) loaded to an assembly line for assembling PCB electronic circuits (PCBAs), the method comprising: providing serialization data on at least one surface of an object (ID-Chip) having a form factor of that is mountable to a printed circuit board by a pick and place (P&P) robot of a PCB A assembly line; and using the P&P robot to position the ID-Chip on a PCB on which the PCBA assembly line assembles electronic components to produce PCBAs.

WO

### RELATED APPLICATIONS

The present application claims the benefit under 35 U.S.C. 119(e) of U.S. Provisional Application 63/417,063 filed on Oct. 18, 2022, the disclosure of which is incorporated herein by reference.

### FIELD

Embodiments of the invention relate to labeling printed circuit boards (PCBs) with unique IDs.

### BACKGROUND

Traceability in manufacturing refers to technology that enables identifying a particular component of a manufactured product and tracing the component history in a manufacturing process of the product back to an advantageous point of entry of the component into the manufacturing process. It is a bedrock technology that underpins the monitoring and quality control of the complex devices and systems that color, if not determine, almost every aspect of modern human activity to assure that the devices and systems perform at acceptable levels of safety and reliability. Traceability enables by way of example, modern forms of play, communications, transportation, management, biotechnology, and medicine.

In the electronics industry that produces, configures, and assembles the ever-present electronic circuits that provide, support, and/or format the devices and systems, traceability is provided by providing logistical data on electronic components of the electronic circuits, and on packaging units (PUs) in which the components are delivered to manufacturers of the circuits.

For the highly automated, predominant method of manufacturing printed circuit board (PCB) electronic circuits referred to as surface mounted technology (SMT), PCBs are fed to a PCB assembly line to have electronic components of the circuits assembled on the PCBs by pick and place (P&P) robots installed at various stations of the assembly line. The components are generally provided in PUs that are configured ready for mounting to or access by the P&P robots. The robots remove the components from the PUs and carefully position the components at their designated locations on PCB traces formed on the PCBs so that conductive leads of the components are in contact with the traces. SMT ready PUs may be in the form of reels, trays, stick magazines, or bulk. Following positioning of the components on the traces the components are fixed and electrically connected to the traces by a soldering process, such as a reflow or wave soldering process.

For reference, testing, and traceability of assembled PCB electronic circuits (PCBAs) it is advantageous, in addition to having traceability data generally available from PUs and electronic components to label PCBs that are entered into and moved along a PCBA assembly line with data, “serialization data”, that serializes the PCBs with unique IDs and/or logistical data.

Serialization is conventionally done by manual or automatic application of serialization data to PCBs that enter, or are to be entered, into a PCBA line. Manual application typically requires applying serialization labels to PCBs and is slow, labor intensive, and generally unsuited for large scale production. Automatic serialization, whether by laser engraving or labeling with labels, typically requires installation in a PCBA line of dedicated, often relatively expensive, high maintenance equipment that operates to respectively engrave or attach labels printed with serialization data on PCBs. Application of serialization data to PCBs, whether by conventional manual or automatic methods, generally requires installation to a PCBA line of special imaging equipment to read the applied serialization data for transmission to a manufacturing execution system (MES) associated with the PCBA line. As a result, PCBA manufactures too often forego serializing PCBs.

### SUMMARY

An aspect of an embodiment of the disclosure relates to providing methods and devices for serializing PCBs that enter a PCBA assembly line for manufacture of PCBAs with ID and/or logistical serializing data. In accordance with an embodiment serializing PCBs does not require installation of dedicated labeling, engraving, and/or imaging equipment in the assembly line to serialize the PCBs. Serializing data may be applied to the PCBs by the same P&P robots in the PCBA line that place electronic components on the PCBs and is read by the same imaging equipment in the PCBA line that is used to image the components and monitor PCBA production.

In accordance with an embodiment serializing data is provided for the PCBA assembly line by objects, hereinafter also referred to as ID-Chips, each bearing serializing data on at least one surface of the ID-Chip and having a physical form factor resembling that of any of various shapes that are handled by P&P robots in the assembly line. The ID-Chips may be formed from any material that maintains suitable integrity during PCBA assembly and after assembly during use. By way of example, an ID chip in accordance with an embodiment may have a form factor of an IC package and be formed from a material used to encapsulate a semiconductor integrated circuit and/or from a PCB material. For affixing to the PCBs the ID-Chips may have a configuration of contact leads for through hole or SMT assembly to the PCBs as may be required by a method of assembly used in the PCBA assembly line. Alternatively or additionally, the ID-Chip and/or the PCBs may comprise an adhesive surface region for affixing the ID-Chips to the PCBs. The ID-Chips are provided in PUs suitable for use by a P&P robot in the PCBA line and are placed on the PCBs by the P&P robot. After placement, ID-Chips having an array of contact leads may be fixed in place by a same process used in the PCBA line to electrically connect electronic components to conductive traces on the PCBs. For ID-Chips and/or PCBs having an adhesive region for affixing ID-Chips, the ID-Chips may be affixed to the PCBs by contact and/or heating in a same process used to establish solder contact of electronic components to the PCBs.

In an embodiment the serializing data is located on the at least one surface so that it may be imaged by an imager in the assembly line that is used to monitor placement of electronic components assembled by P&P machines to the PCBs. Optionally, the serializing data is located on two surfaces of the ID-Chips. Optionally, the serializing data on one of the surfaces comprises an encryption of the serializing data on the other surface.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE FIGURES

Non-limiting examples of embodiments of the disclosure are described below with reference to figures attached hereto that are listed following this paragraph. Identical features that appear in more than one figure are generally labeled with a same label in all the figures in which they appear. A label labeling an icon representing a given feature in a figure of an embodiment of the disclosure may be used to reference the given feature. Dimensions of features shown in the figures are chosen for convenience and clarity of presentation and are not necessarily shown to scale

FIG. 1 schematically shows an SMT assembly line comprising a dedicated PCB serializing machine, in accordance with prior art;

FIG. 2 schematically shows an SMT assembly line that does not require a dedicated PCB serializing machine, and instead serializes PCBs by assembling to the PCBs ID-Chips, in accordance with an embodiment of the disclosure; and

FIGS. 3A and 3B schematically show top and bottom surfaces bearing serializing data of an ID-Chip, in accordance with an embodiment of the disclosure.

### DETAILED DESCRIPTION

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment in an application for which it is intended. Wherever a general term in the disclosure is illustrated by reference to an example instance or a list of example instances, the instance or instances referred to, are by way of non-limiting example instances of the general term, and the general term is not intended to be limited to the specific example instance or instances referred to. The phrase “in an embodiment”, whether or not associated with a permissive, such as “may”, “optionally”, or “by way of example”, is used to introduce for consideration an example, but not necessarily required, configuration of possible embodiments of the disclosure. Each of the verbs, “comprise” “include” and “have”, and conjugates thereof, are used to indicate that the object or objects of the verb are not necessarily a complete listing of components, elements or parts of the subject or subjects of the verb. Unless otherwise indicated, the word “or” in the description and claims is considered to be the inclusive “or” rather than the exclusive or, and indicates at least one of, or any combination of more than one of items it conjoins.

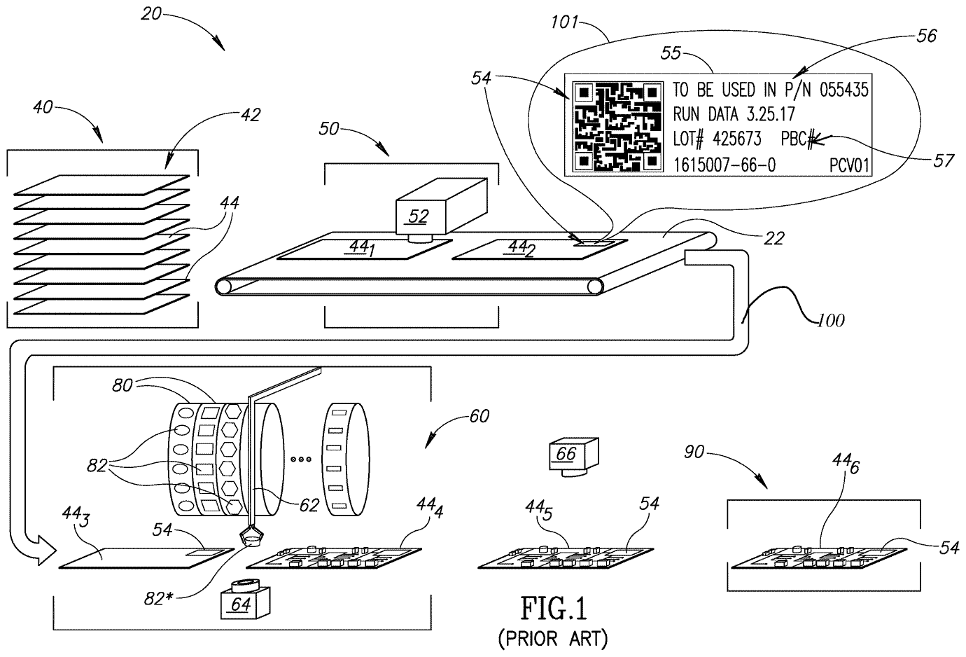

FIG. 1 shows a schematic snapshot image of an SMT assembly line 20 assembling PCBAs and serializing PCBs that the SMT line uses to assemble the PCBAs in accordance with prior art. SMT assembly line 20 is shown very schematically and comprises a PCB line loader 40 supplied with a stack 42 of PCBs 44, a PCB labeling machine 50, a P&P robot 60, and a reflow oven 90.

PCBs 44 in stack 42 are assumed to be printed with traces (not shown) and PCB line loader 40 loads PCBs 44 bare of electronic components to a conveyor belt 22 to move the bare PCBs through PCB labeling machine 50 and thereafter through SMT line 20 to have the SMT line assemble electronic components on the PCBs. A bare PCB 441 loaded by PCB line loader 40 onto the conveyor belt is shown positioned below a labeling head 52 of labeling machine 50 to have a serializing label attached to PCB 201 by the labeling head. A PCB 202 is schematically shown being transported by conveyor belt 22 after being labeled with a serializing label 54 and leaving labeling machine 50 to proceed, as indicated by a direction block arrow 100, to P&P robot 60. It is noted that labeling machine 50 may operate by printing and attaching serializing labels to PCBs or by attaching preprinted serializing labels to PCBs.

Label 54 is shown greatly enlarged in an inset 101 and optionally comprises a QR code 55 and alphanumeric data 56. QR code 55 and alphanumeric data 56 may comprise in addition to a serializing ID number 57, logistical data such as the PCB origin, associated lot numbers, and/or soldering temperature data. Label 54 may be made from any of various materials that are advantageously durable and resistant to damage by heat, chemical, and/or mechanical stress that may be encountered during assembly and thereafter during storage of PCBAs produced by SMT line 20 comprising PCBs 44. By way of example label 54 may be made from a polyester, polyamide, polypropylene, and/or polyimide substrate, have QR code 55 and alphanumeric data printed with resin inks, and may be attached to PCB 442 with an adhesive such as an acrylic adhesive.

Following labeling by labeling machine 50 a labeled PCB 44 proceeds to P&P robot 60. P&P robot 60 is assumed to be configured to receive electronic components for positioning on PCBs 44 from component reels and the P&P robot is shown loaded with a plurality of component reels 80 comprising a variety of electronic components 82 that are to be assembled on PCBs 44 that line loader 40 loads to SMT line 20. P&P robot 60 comprises a P&P robotic arm 62 for removing components 82 from reels 80 and placing the components on PCB boards 44 and an operations camera 64 for assisting and monitoring operation of the P&P robot. Operations camera 64 is configured and posed to acquire an image of a bottom of a component 82 that P&P robot 60 removes from a reel 80 to place on a PCB 44 that shows a configuration of conductive leads of the component which are intended to electrically connect the component to a designated trace or traces of the PCB. P&P robot 60 uses the image to properly position the component so that the leads are accurately positioned to contact the designated trace/s.

FIG. 1 schematically shows P&P robot 60 having a PCB 443 that has just entered the P&P robot from labeling machine 50 and a PCB 444 that is about to leave the P&P robot. PCB 443 that has just entered P&P robot 60 does not as yet have an electronic component 82 from a reel 80 placed on PCB 443, and PCB 444 exiting the P&P robot is shown after having all electronic components 82 that are to be assembled on PCB 444 to produce a PCBA mounted on PCB 444. Robotic arm 62 is shown having removed a given electronic component 82, individualized by a label 82*, from a reel 80 to be placed as a first component to be assembled to PCB 443. Operations camera 64 is shown imaging component 82* from the bottom to provide P&P robot 60 with an image of a pattern of conductive leads of the component to aid the robot in accurately positioning the component on PCB 443.

In addition to an image of the pattern of conductive leads on the bottom of component 82*, the image acquired by operations camera 64 may also include an image of component traceability data, such as by way of example, a component serial number, manufacturer ID, and date of manufacture, residing on the bottom of component. The image is generally transmitted to a MES (not shown) associated with SMT assembly line 20 for processing to extract and store the traceability data as a portion of a traceability record of a circuit, “PCBA 443”, assembled by the SMT line on PCB 443.

Following exit from P&P robot 60 a PCB having all components required by a PCBA produced by SMT 20 may be imaged by a top automatic optical inspection (AOI) camera 66 to provide data for monitoring quality of the PCBA before moving the PCB into reflow oven 90 for permanently bonding end electrically connected the components to the traces of the PCB. Similarly to the case of operations camera 64, images acquired by AOI camera 66 of tops of electronic components placed on the PCB comprises images of traceability data that may be present on the tops. The images are generally transmitted to the MES associated with SMT line 20 for processing to extract and store the traceability data as a portion of a traceability record of a circuit, assembled on the PCB. FIG. 1 schematically shows top AOI camera 66 imaging a PCB 445 that has exited P&P robot 60 after the P&P robot has completed placing components 82 on PCB 445. FIG. 1 also shows a PCB 446 in reflow oven 90 being heated to solder the contact leads of components 82 to their respective designated traces of PCB 446 after PCB 446 has been imaged by AOI camera 66.

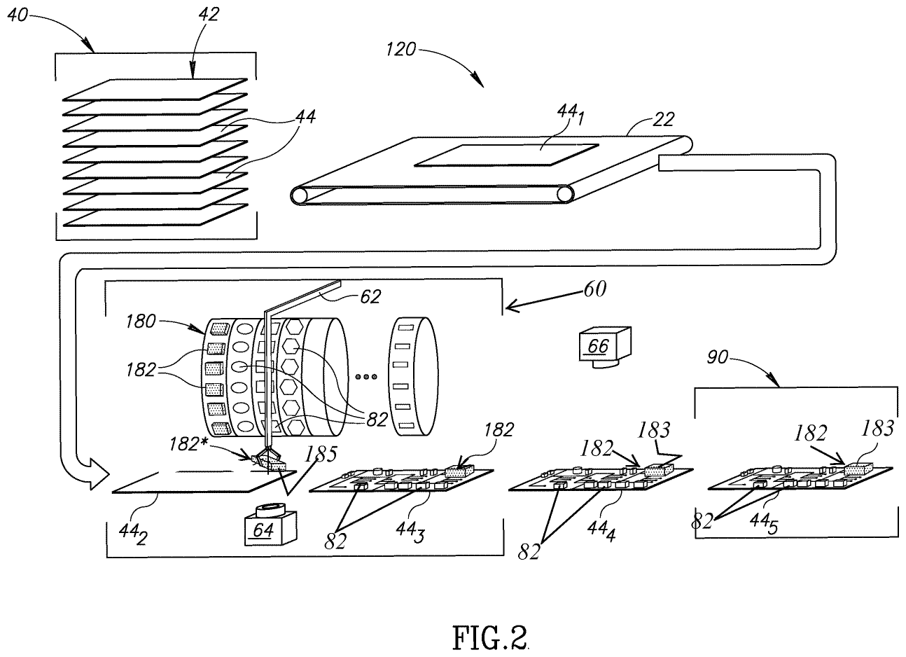

FIG. 2 shows a schematic snapshot image of an SMT assembly line 120 optionally assembling the same PCBAs as assembled by SMT line 20 shown in FIG. 1 and serializing PCBs that the SMT line processes to assemble the PCBAs using ID-Chips instead of labels 54 (FIG. 1), in accordance with an embodiment of the disclosure.

SMT line 120 is optionally the same as SMT line 20 except for the absence of serializing machine 50. Line loader 40 loads PCBs 44 onto conveyor 22 which optionally transports the PCBs to P&P robot 60 without being labeled with serializing data prior to entry into the P&P robot. P&P robot 60 is optionally loaded with the same reels 80 that are loaded to P&P robot 60 in SMT line 20 and operates similarly to P&P robot 60 in SMT 20 to remove and place electronic components 82 from reels 80 onto the PCBs.

However, in accordance with an embodiment of the disclosure P&P robot 60 is also loaded with a reel 180 having ID-Chips 182 comprising serializing data for serializing PCBs 44, in accordance with an embodiment of the disclosure. P&P robot 60 removes ID-Chips from reel 180 and places the ID-Chips on PCBs 44 to serialize the PCBs, in the same way that the P&P robot operates to place electronic components 82 on the PCBs.

FIG. 2 shows an unlabelled PCB 441 that line loader 40 loads onto conveyor belt 22 for processing by SMT line 120, an unlabelled PCB 442 that has just entered P&P 60 from the conveyor belt, and a PCB 443 that is about to leave the P&P robot. PCB 442 that has just entered P&P robot 60 is unlabelled with serializing data and does not as yet have an electronic component 82 from a reel 80 placed on PCB 442. PCB 443 exiting the P&P robot is shown after having all electronic components 82 that are to be assembled on PCB 443 to produce a PCBA placed on PCB 443 and having an ID-Chip 182, from reel 180 placed on PCB 443 by P&P robotic arm 62, in accordance with an embodiment of the disclosure.

Robotic arm 62 is shown having removed a given ID-Chip 180, individualized by a label 182*, from reel 180 to be placed on unlabelled PCB 442 to serialize PCB 442 with serializing data. Operations camera 64 is shown imaging ID-Chip 182* from the bottom to acquire an image of a bottom surface 185 of ID-Chip 182* and provide P&P robot 60 with an image of conductive leads of ID-Chip 182* to aid the robot in accurately positioning the component on PCB 443. In an embodiment ID-Chips 182 have “bottom” serializing data on their bottom surfaces 185 and the image that operations camera 64 acquires of bottom surface 185 of ID-Chip 182* also images the bottom serializing data. As in the case of electronic components 82 placed on PCBs processed by SMT line 120, the images of bottom surfaces 185 of ID-Chips 182 may be forwarded to a MES associated with the PCBA line. And just as the MES processes bottom images of components 82 to extract and store traceability data in the bottom images of components 82, the MES processes bottom images 185 to extract and store bottom serialization data from the bottom as portions of traceability records of PCBAs, assembled by EMT line 120 on PCBs serialized by ID-Chips 182.

Following exit from P&P robot 60 a PCB having an ID-Chip 182 and all components 82 required by a PCBA produced by SMT 20 may be imaged by AOI camera 66 to provide data for monitoring quality of the PCBA before moving the PCB into reflow oven 90 for permanently bonding end electrically connected the components to the traces of the PCB. In an embodiment ID-Chips 182 have serializing data on their top surfaces 183 and images that AOI camera 66 acquires of top surfaces 183 of ID-Chips 182 on PCBs 44 also image the “top” serialization data. In an embodiment the top images of PCBs acquired by AOI camera 66 are forwarded to a MES for processing to extract and store top serialization data from ID-Chips 182 and traceability data from top surfaces of components 82.

FIG. 2 schematically shows AOI camera 66 imaging a PCB 444 that has exited P&P robot 60 from the top after P&P robot 60 has completed placing components 82 and an ID-Chip 182 on PCB 444. The top image of PCB 444 acquired by AOI camera 66 images the tops of components 82 and top 183 of ID-Chip 182 on PCB 444. In accordance with an embodiment the image is transmitted to the MES associated with SMT line. The MES processes the top images to extract traceability data from the top images of components 82 and serialization data from the top image of ID-Chip 182 and store the extracted traceability and serialization data as portions of a traceability record of a PCBA assembled on PCB 444. The figure also schematically shows a PCB 445 in reflow oven 90 after being imaged by AOI camera 66. In the reflow oven PCB 445 is heated to solder the contact leads of components 82 and ID-Chip 182 to designated traces of PCB 445.

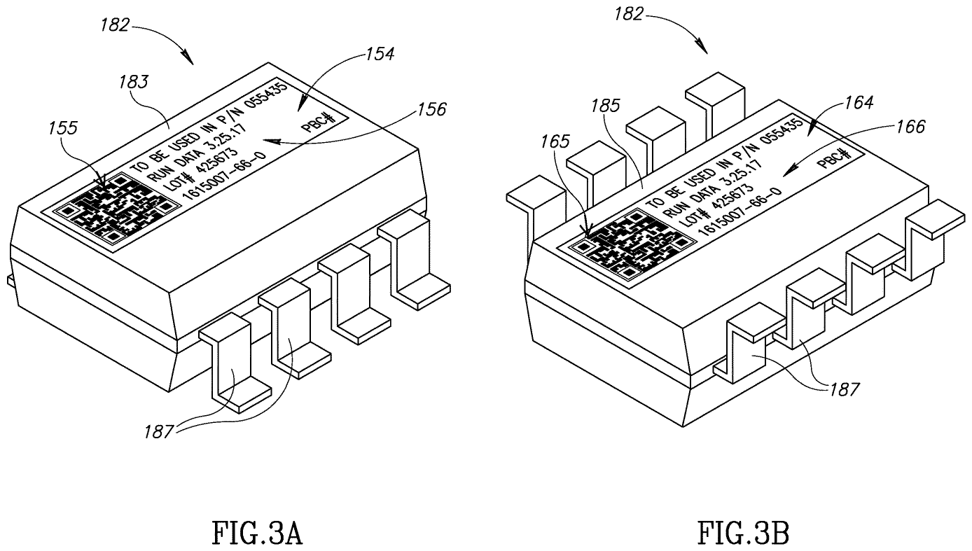

FIGS. 3A and 3B schematically show top and bottom perspective views respectively of an ID-Chip 182, in accordance with an embodiment of the disclosure.

ID-Chip 182 optionally has a form factor of an IC chip and L-shaped contact leads 187 of a small outline IC chip package that are suitable for SMT assembly. The ID-Chip optionally has top serializing data 154 on a top surface 183 (FIG. 3A) of the ID-Chip. The ID-Chip optionally has bottom serializing data 164 on a bottom surface 185 (FIG. 3B) of the ID-Chip. In an embodiment the top serializing data comprises a QR code 155 and alphanumeric data 156. Bottom serializing data 164 optionally comprises a QR code 165 and alphanumeric data 166.

Optionally, as shown in FIGS. 3A and 3B serializing data 154 and 164 on top and bottom surfaces 183 and 184 respectively of ID-Chip 182 are the same. Optionally, top serializing data 154 is different from bottom serializing data 164. In an embodiment, one of the top and bottom serializing data 154 and 164 comprises an encryption of at least some of the data comprised in the other of the top and bottom serializing data. Optionally, one of the top and bottom serializing data 154 and 164 comprises a hash of at least some of the data comprised in the other of the serializing data. Optionally the hash is salted.

It is noted that whereas ID-Chip 180 is shown having a rectangular shape and L-shaped contact leads 187 for soldering the ID-Chip to a PCB trace, embodiments of the invention are not limited to rectangular shapes and L-shaped leads. Any configuration of an SMT or through hole technology (THT) conductive contact leads or surfaces may be used for soldering an ID-Chip to traces of a PCB, in accordance with an embodiment of the disclosure.

For example, an ID-Chip in accordance with an embodiment may comprise a ball grid array for soldering compatible with an SMT or through hole wire leads for soldering compatible with THT. And an ID-Chip may have any of various shapes, such as circular or octangular shapes, in accordance with an embodiment of the disclosure.

It is further noted that whereas in the discussion above and FIG. 2 respectively describe and schematically show ID-Chips provided in PUs that are reels for loading to a P&P robot, embodiments of the disclosure are not limited to ID-Chips provided in reels. ID-Chips may be provided in any PU suitable for loading to a P&P robot of an SMT and/or a THT line and may be provided for manually mounting to a PCB. ID-Chips in accordance with an embodiment may for example be provide in reels, trays, stick magazines, or bulk.

There is therefore provided in accordance with an embodiment of the disclosure a method of serializing printed circuit boards (PCBs) loaded to an assembly line for assembling PCB electronic circuits (PCBAs), the method comprising: providing serialization data on at least one surface of an object (ID-Chip) having a form factor of that is mountable to a printed circuit board by a pick and place (P&P) robot of a PCBA assembly line; and using the P&P robot to position the ID-Chip on a PCB on which the PCBA assembly line assembles electronic components to produce PCBAs. Optionally the method comprises acquiring an image of the serialization data on a first surface of the at least one surface with an operations imager comprised in the PCBA assembly line. Optionally, the first surface is a surface that faces a surface of the PCB when the ID-Chip is positioned on the PCB by the P&P robot. Optionally, the first surface is a bottom surface of the ID-Chip. Additionally, or alternatively, the operations imager may transmit the image of the serialization data on the first surface to a manufacturing execution system (MES) and/or a traceability management tool associated with the PCBA assembly line.

In an embodiment the method comprises acquiring an image of the serialization data on a second surface of the at least one surface with an automatic optical inspection (AOI) imager comprised in the PCBA assembly line. Optionally, the second surface is a surface that faces away from a surface of the PCB when the ID-Chip is positioned on the PCB by the P&P robot. Optionally, the second surface is a top surface of the ID-Chip. Additionally, or alternatively, the AOI imager may transmit the image of the serialization data on the second surface to a manufacturing execution system (MES) and/or a traceability management tool associated with the PCBA assembly line.

In an embodiment the method comprises the at least one surface comprises two surfaces. In an embodiment the method comprises the serialization data on one surface of the two surfaces comprises an encryption of data comprised in the serialization data on the other of the two surfaces. In an embodiment the method comprises the ID-Chip has a form factor of an electronic component that the P&P robot places on PCBs on which the PCBA assembly line assembles PCBAs. Optionally, the ID-Chip has a form factor of an integrated circuit (IC) chip. Optionally, the IC chip is configured for assembly by a surface mount technology. Optionally, the IC chip is configured for through hole assembly.

In an embodiment the method the serializing data comprises an image. Optionally, the image comprises a barcode. Additionally, or alternatively, the image may comprise a QR image. In an embodiment the the serialization data comprises an alphanumeric symbol.

In an embodiment the method the ID-Chip is provided to the P&P robot in a packaging unit (PU) type that is the same as a PU type in which electronic components that the P&P robot places on PCBs are provided to the P&P robot.

Descriptions of embodiments of the invention in the present application are provided by way of example and are not intended to limit the scope of the invention. The described embodiments comprise different features, not all of which are required in all embodiments of the invention. Some embodiments utilize only some of the features or possible combinations of the features. Variations of embodiments of the invention that are described, and embodiments of the invention comprising different combinations of features noted in the described embodiments, will occur to persons of the art. The scope of the invention is limited only by the claims.

1. A method of serializing printed circuit boards (PCBs) loaded to an assembly line for assembling PCB electronic circuits (PCBAs), the method comprising:
providing serialization data on at least one surface of an object (ID-Chip) having a form factor of that is mountable to a printed circuit board by a pick and place (P&P) robot of a PCBA assembly line; and
using the P&P robot to position the ID-Chip on a PCB on which the PCBA assembly line assembles electronic components to produce PCBAs.

2. The method according to claim 1 and comprising acquiring an image of the serialization data on a first surface of the at least one surface with an operations imager comprised in the PCBA assembly line.

3. The method according to claim 2 wherein the first surface is a surface that faces a surface of the PCB when the ID-Chip is positioned on the PCB by the P&P robot.

4. The method according to claim 2 wherein the first surface is a bottom surface of the ID-Chip.

5. The method according to claim 3 wherein the operations imager transmits the image of the serialization data on the first surface to a manufacturing execution system (MES) and/or a traceability management tool associated with the PCBA assembly line.

6. The method according to claim 1 and comprising acquiring an image of the serialization data on a second surface of the at least one surface with an automatic optical inspection (AOI) imager comprised in the PCBA assembly line.

7. The method according to claim 6 wherein the second surface is a surface that faces away from a surface of the PCB when the ID-Chip is positioned on the PCB by the P&P robot.

8. The method according to claim 6 wherein the second surface is a top surface of the ID-Chip.

9. The method according to claim 7 wherein the AOI imager transmits the image of the serialization data on the second surface to a manufacturing execution system (MES) and/or a traceability management tool associated with the PCBA assembly line.

10. The method according to claim 1 wherein the at least one surface comprises two surfaces.

11. The method according to claim 1 wherein the serialization data on one surface of the two surfaces comprises an encryption of data comprised in the serialization data on the other of the two surfaces.

12. The method according to to claim 1 wherein the ID-Chip has a form factor of an electronic component that the P&P robot places on PCBs on which the PCBA assembly line assembles PCBAs.

13. The method according to claim 12 wherein the ID-Chip has a form factor of an integrated circuit (IC) chip.

14. The method according to claim 13 wherein the IC chip is configured for assembly by a surface mount technology,

15. The method according to claim 13 wherein the IC chip is configured for through hole assembly.

16. The method according to claim 1 wherein the serializing data comprises an image.

17. The method according to claim 16 wherein the image comprises a barcode.

18. The method according to claim 16 wherein the image comprises a QR image

19. The method according to claim 1 wherein the serialization data comprises an alphanumeric symbol.

20. The method according to claim 1 wherein the ID-Chip is provided to the P&P robot in a packaging unit (PU) type that is the same as a PU type in which electronic components that the P&P robot places on PCBs are provided to the P&P robot.
